(19) United States
(12) Patent Application Publication
(10) Pub. No.: US 2026/0171362 A1
(43) Pub. Date: Jun. 18, 2026

(54) SUBSTRATE TREATING APPARATUS

(71) Applicant: SAMSUNG ELECTRONICS CO., LTD., Suwon-si (KR)

(72) Inventors: Seong June JEONG, Suwon-si (KR); Hyug-Jung Yong, Suwon-si (KR); Han Byul Kang, Suwon-si (KR); Jae Ho Kim, Suwon-si (KR)

(73) Assignee: SAMSUNG ELECTRONICS CO., LTD., Suwon-si (KR)

(21) Appl. No.: 19/250,952

(22) Filed: Jun. 26, 2025

(30) Foreign Application Priority Data
Dec. 18, 2024 (KR) 10-2024-0189794

(51) Int. Cl. H01J 37/32; H01L 21/67

(52) U.S. Cl. CPC H01J 37/3222; H01J 37/32522; H01J 2237/002; H01J 2237/334; H10P 72/0402; H10P 72/0454

(57) ABSTRACT

A substrate treating apparatus includes a chamber housing, a substrate support in the chamber housing and configured to support a substrate, a process gas supply connected to the chamber housing and configured to supply a process gas, and a plasma generator configured to generate plasma in the chamber housing using a microwave, where the plasma generator includes an antenna, a connector connecting the antenna to a coaxial cable configured to provide the microwave, a cover covering the antenna, and a microwave transmission portion connected to the connector, where at least a portion of the antenna and at least a portion of the cover are inside the microwave transmission portion, and the connector seals an inside of the microwave transmission portion in a vacuum state.

### CROSS-REFERENCE TO RELATED APPLICATION

This application is based on and claims priority to Korean Patent Application No. 10-2024-0189794, filed on Dec. 18, 2024, in the Korean Intellectual Property Office, the disclosure of which is incorporated by reference herein in its entirety.

### BACKGROUND

### 1. Field

The present disclosure relates to an apparatus for treating a substrate using plasma.

### 2. Description of Related Art

A substrate treating apparatus for treating a substrate using microwave plasma may use a surface wave plasma source to generate high-density plasma.

However, the apparatus may encounter various issues. First, an electric field is concentrated on a central area, thereby causing an electric field distribution imbalance. Second, when a high output is used, a mode change phenomenon occurs, and it is difficult to control a density in a linear manner. Third, it may not be possible to generate large-area plasma at a high pressure, and plasma is locally generated, thereby deteriorating uniformity. Fourth, a bulky waveguide should be used, and a system structure becomes very complex.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate treating apparatus that may be capable of enhancing plasma stability and reliability.

Additional aspects will be set forth in part in the description which follows and, in part, will be apparent from the description, or may be learned by practice of the presented embodiments.

According to an aspect of an example embodiment, a substrate treating apparatus may include a chamber housing, a substrate support in the chamber housing and configured to support a substrate, a process gas supply connected to the chamber housing and configured to supply a process gas, and a plasma generator configured to generate plasma in the chamber housing using a microwave, where the plasma generator may include an antenna, a connector connecting the antenna to a coaxial cable configured to provide the microwave, a cover covering the antenna, and a microwave transmission portion connected to the connector, where at least a portion of the antenna and at least a portion of the cover are inside the microwave transmission portion, and the connector seals an inside of the microwave transmission portion in a vacuum state.

According to an aspect of an example embodiment, a substrate treating apparatus may include a chamber housing, a substrate support in the chamber housing and configured to support a substrate, a process gas supply connected to the chamber housing and configured to supply a process gas, and a plasma generator configured to generate plasma in the chamber housing using a microwave, where the plasma generator may include an antenna, a connector connecting the antenna to a coaxial cable configured to provide the microwave, a cover covering the antenna, and a microwave transmission portion connected to the connector, where at least a portion of the antenna and at least a portion of the cover are inside the microwave transmission portion, the connector seals an inside of the microwave transmission portion in a vacuum state, and the process gas supply is configured to supply the process gas to an inner space of the chamber housing via the plasma generator.

According to an aspect of an example embodiment, a substrate treating apparatus may include a chamber housing, a substrate support in the chamber housing and configured to support a substrate, a process gas supply connected to the chamber housing and configured to supply a process gas, and a plasma generator configured to generate plasma in the chamber housing using a microwave, where the plasma generator may include an antenna, a connector connecting the antenna to a coaxial cable configured to provide the microwave, a cover covering the antenna, and a microwave transmission portion connected to the connector, where at least a portion of the antenna and at least a portion of the cover are inside the microwave transmission portion, the connector seals an inside of the microwave transmission portion in a vacuum state, the process gas supply is directly connected to the chamber housing, and the plasma generator is directly connected to the chamber housing.

### BRIEF DESCRIPTION OF DRAWINGS

The above and other aspects, features, and advantages of certain example embodiments of the present disclosure will be more apparent from the following description taken in conjunction with the accompanying drawings, in which:

FIGS. 1 to 3 are diagrams illustrating examples of semiconductor manufacturing equipment according to one or more embodiments;

FIG. 4 is a diagram illustrating an internal structure of a substrate treating apparatus according to one or more embodiments;

FIG. 5 is a diagram illustrating a substrate support constituting a substrate treating apparatus according to one or more embodiments;

FIGS. 6 to 8 are diagrams illustrating examples of an internal structure of a substrate treating apparatus according to one or more embodiments;

FIG. 9 is a diagram illustrating an internal structure of a plasma generator constituting a substrate treating apparatus according to one or more embodiments;

FIGS. 10 to 13 are diagrams illustrating examples of a structure of a connector constituting a plasma generator in a substrate treating apparatus according to one or more embodiments;

FIGS. 14 to 20 are example diagrams illustrating a structure of an antenna constituting a plasma generator in a substrate treating apparatus according to one or more embodiments; and

FIGS. 21 and 22 are example diagrams illustrating an internal structure of a plasma generator constituting a substrate treating apparatus according to one or more embodiments.

### DETAILED DESCRIPTIONS

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The substrate treating apparatus may treat a substrate using plasma. The substrate treating apparatus may treat the substrate using one of an etching process, a cleaning process, a deposition process, and an ion implantation process. Hereinafter, a case of treating the substrate using the etching process will be described by way of example, and aspects of the disclosure may be equally applied to each of the processes other than the etching process. Hereinafter, semiconductor manufacturing equipment including a substrate treating apparatus will be described first, and then the substrate treating apparatus will be described.

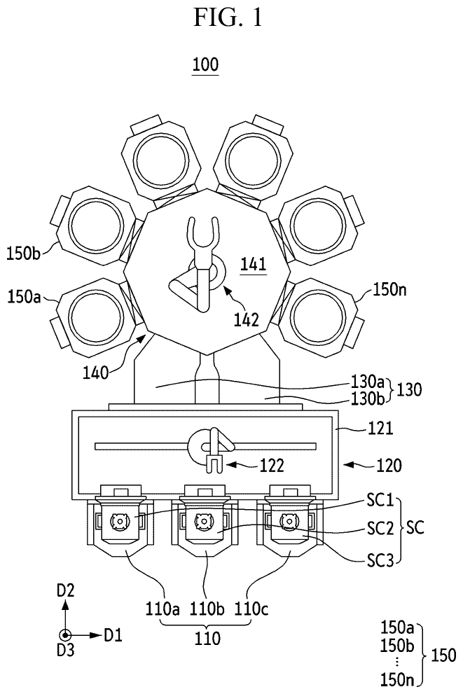

FIGS. 1 to 3 are diagrams illustrating semiconductor manufacturing equipment according to one or more embodiments.

A first direction D1 and a second direction D2 may define a two-dimensional plane. The first direction D1 may be an X-axis direction, and the second direction D2 may be a Y-axis direction. The first direction D1 may be a left-right direction, and the second direction D2 may be a front-back direction. Alternatively, the first direction D1 may be a forward-backward direction, and the second direction D2 may be a left-right direction. The first direction D1, the second direction D2 and a third direction D3 may define a three-dimensional solid. The third direction D3 is a direction perpendicular to the plane defined by the first direction D1 and the second direction D2. The third direction D3 may be a Z-axis direction. The third direction D3 may be a vertical direction.

Referring to FIG. 1 to FIG. 3, semiconductor manufacturing equipment 100 may be configured to include a load port module 110, an index module 120, a buffer module 130, a transfer module 140, and a process treating module 150.

The load port module 110 may provide a seat surface on which a container SC is seated. The container SC may be transported to the load port module 110 by an overhead transport apparatus or a ground-based transport apparatus. The container SC may accommodate therein a plurality of substrates. For example, the container SC may be provided as a front opening unified pod (FOUP). The overhead transport apparatus may move on a ceiling of the semiconductor manufacturing plant and transport the container SC. For example, the overhead transport apparatus may be provided as an Overhead hoist transport (OHT). The ground-based transport apparatus may move on a ground of the semiconductor manufacturing plant and transport the container SC. For example, the ground-based transport apparatus may be provided as an autonomous mobile robot (AMR) or an automatic guided vehicle (AGV).

The container SC may be loaded into or unloaded from the load port module 110. The substrates stored in the container SC may be loaded into or unloaded from the load port module 110.

A plurality of load port modules 110 may be disposed in front of the index module 120. For example, three load ports 110a, 110b, and 110c including the first load port 110a, the second load port 110b, and the third load port 110c may be disposed in front of the index module 120. The three load ports 110a, 110b, and 110c may be arranged in the horizontal direction D1. However, embodiments are not limited thereto and the three load ports 110a, 110b, and 110c may be arranged in the vertical direction D3.

When the load port module 110 includes the three load ports 110a, 110b, and 110c, the containers SC respectively seated on the load ports 110a, 110b, and 110c may store therein different types of objects, respectively. For example, a first container SC1 seated on the first load port 110a may store therein a wafer-type sensor, a second container SC2 seated on the second load port 110b may store therein a substrate, and a third container SC3 seated on the third load port 110c may store therein a consumable part such as a focus ring and an edge ring. However, embodiments are not limited thereto, and the containers SC respectively seated on the load ports 110a, 110b, and 110c may store therein objects of the same type, respectively. Alternatively, the containers SC respectively seated on some load ports among a plurality of load ports may store therein objects of the same type, respectively.

The index module 120 may be disposed between the load port module 110 and a buffer module 130. The index module 120 may be provided as an interface for substrate transfer between the load port module 110 and the buffer module 130. The index module 120 may include a first module housing 121 and the first transport robot 122. The first module housing 121 may have an atmospheric pressure environment in an inside thereof. The first transport robot 122 may be disposed inside the first module housing 121 and may transport the substrate in the atmospheric pressure environment. The first transport robot 122 may include a single first transport robot or a plurality of first transport robots received inside the first module housing 121.

The index module 120 may include a buffer chamber. The buffer chamber may temporarily store therein a non-treated substrate before transporting the same to the buffer module 130. The buffer chamber may temporarily store therein a treated substrate before transporting the same to the container SC on the load port module 110. The buffer chamber may include a single buffer chamber or a plurality of buffer chamber defined in an inner wall of the first module housing 121.

The semiconductor manufacturing equipment 100 may include an equipment front end module (EFEM). The equipment front end module may include the load port module 110 and the index module 120.

The buffer module 130 may be disposed between the index module 120 and the transfer module 140. The buffer module 130 may receive a buffer stage therein. The buffer stage may temporarily store therein a non-treated substrate or a treated substrate. The buffer module 130 may include a plurality of buffer modules. For example, the buffer module 130 may include a first load lock chamber 130a and a second load lock chamber 130b.

The two load lock chambers 130a and 130b may be arranged in the horizontal direction D1. However, embodiments of the present disclosure are not limited thereto, and the two load lock chambers 130a and 130b may be arranged in the vertical direction D3. The two load lock chambers 130a and 130b may be arranged in the same direction as the arrangement direction of the three load ports 110a, 110b, and 110c, or in a different direction from the arrangement direction of the three load ports 110a, 110b, and 110c.

The first load lock chamber 130a and the second load lock chamber 130b may provide different functions. For example, one of the first load lock chamber 130a and the second load lock chamber 130b may store therein the non-treated substrate, while the other thereof may store therein the treated substrate. However, embodiments are not limited thereto, and the first load lock chamber 130a and the second load lock chamber 130b may provide the same function. Each of the first load lock chamber 130a and the second load lock chamber 130b may store therein any substrate regardless of whether the substrate has been treated.

The buffer module 130 may change an inside thereof into either a vacuum environment or an atmospheric pressure environment using a gate valve. The buffer module 130 may change the inside thereof into an environment identical to or similar to an internal environment of the index module 120. When the first transport robot 122 loads the substrate into the buffer module 130 or the first transport robot 122 unloads the substrate from the buffer module 130, the buffer module 130 may perform the above function. The buffer module 130 may prevent an internal pressure state of the index module 120 from changing.

The buffer module 130 may change the inside thereof into an environment identical or similar to an internal environment of the transfer module 140. When the second transport robot 142 loads the substrate into the buffer module 130 or the second transport robot 142 unloads the substrate from the buffer module 130, the buffer module 130 may perform the above function. The buffer module 130 may prevent an internal pressure state of the transfer module 140 from changing. As will be described later, the second transport robot 142 may be constructed within the transfer module 140.

The transfer module 140 may be disposed between the buffer module 130 and the process treating module 150. The transfer module 140 may be provided as an interface for substrate transfer between the buffer module 130 and the process treating module 150. The transfer module 140 may include a second module housing 141 and the second transport robot 142. The second module housing 141 may have a vacuum environment in an inner space thereof. The second transport robot 142 may be disposed within the second module housing 141 and may transport the substrate in the vacuum environment. The second transport robot 142 may include a single second transport robot or a plurality of second transport robot disposed within the second module housing 141.

The process treating module 150 may include a plurality of process chambers 150a, 150b, . . . , 150n. Each of the process chambers 150a, 150b, . . . , 150n may perform one of an etching process, a cleaning process, a deposition process, and an ion implantation process. The plurality of process chambers 150a, 150b, . . . , 150n may be provided as the same type of process chamber. However, embodiments are not limited thereto, and the plurality of process chambers 150a, 150b, . . . , 150n may be provided as different types of process chambers. The process treating module 150 may include a single process chamber.

The transfer module 140 may be connected to each of the process chambers 150a, 150b, . . . , 150n. The second module housing 141 may include a plurality of sides, and the second transport robot 142 may be configured to freely pivot around each of the sides of the second module housing 141 so that the second transport robot 142 may load or unload the substrate.

Each of the process chambers 150a, 150b, . . . , 150n may treat the non-treated substrate when the non-treated substrate has been provided thereto through the transfer module 140. Each of the process chambers 150a, 150b, . . . , 150n may provide the treated substrate to the transfer module 140.

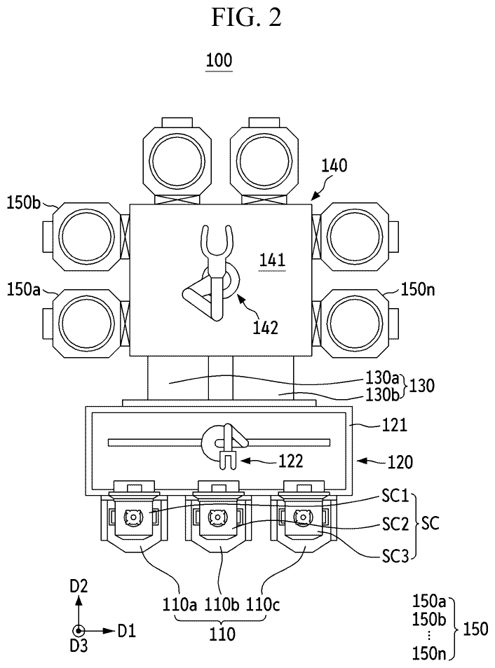

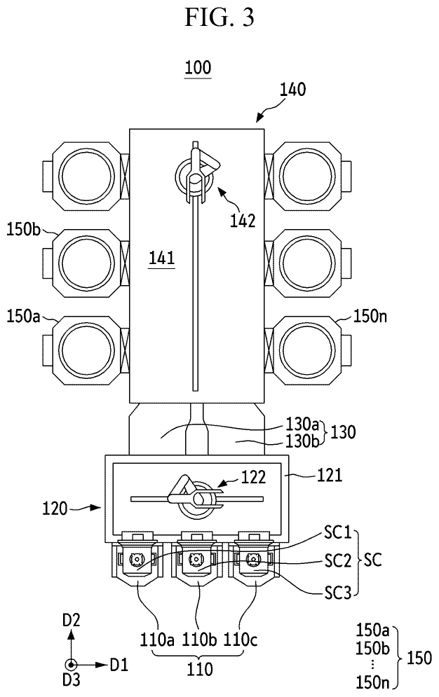

The semiconductor manufacturing equipment 100 may be formed in a cluster platform structure. Referring to FIG. 1, the plurality of process chambers 150a, 150b, . . . , 150n may be arranged in a cluster manner around the transfer module 140. However, embodiments are not limited thereto, and the semiconductor manufacturing equipment 100 may be formed in a quad platform structure. Referring to FIG. 2, the plurality of process chambers 150a, 150b, 150n may be arranged in the quad manner around the transfer module 140. Alternatively, the semiconductor manufacturing equipment 100 may be formed in an inline platform structure. Referring to FIG. 3, the plurality of process chambers 150a, 150b, . . . , 150n may be arranged in an in-line manner around the transfer module 140 as shown in the example of FIG. 3, in which two arrangements of the process chambers may be respectively disposed on both opposing sides of the transfer module 140, and the different process chambers in the two arrangements may face each other in a corresponding manner with each other, and each of the two arrangements may extend in a line.

The semiconductor manufacturing equipment 100 may further include a controller. The controller may control an operation of each of the modules constituting the semiconductor manufacturing equipment 100. For example, the controller may control the substrate transport operation of each of the transport robots 122 and 142, control the internal environmental change of each of the load lock chambers 130a and 130b, and control an overall substrate treatment process of each of the process chambers 150a, 150b, . . . , 150n.

The controller may include a processor that executes control of each of the components constituting the semiconductor manufacturing equipment 100, a network over which the components communicate with each other in a wired manner or wirelessly, one or more instructions related to a function or an operation for controlling each of the components, a memory that stores therein treating recipes including instructions, various data, etc. The controller may further include a user interface including an input means for an operator to perform command input manipulation, etc. to manage the semiconductor manufacturing equipment 100, and an output means for visualizing and displaying the operating status of the semiconductor manufacturing equipment 100. The controller may be embodied as a computing device for data treating and analysis, command transmission, etc.

The instructions may be provided in a form of a computer program or an application. The computer program may be stored in a computer-readable recording medium containing one or more instructions. The instructions may include codes generated by a compiler, codes that may be executed by an interpreter, etc. The memory may be embodied as one or more storage media selected from flash memory, hard disk drive (HDD), solid state drive (SSD), card type memory, random access memory (RAM), static RAM (SRAM), dynamic RAM (DRAM), read-only memory (ROM), electrically erasable programmable ROM (EEPROM), programmable ROM (PROM), magnetic memory, magnetic disk, optical disk, etc.

Next, the substrate treating apparatus will be described. The substrate treating apparatus may treat the substrate using microwave plasma as a plasma source. The substrate treating apparatus may be provided as one of the plurality of process chambers 150a, 150b, . . . , 150n. For example, the first process chamber 150a may be provided as the substrate treating apparatus using the microwave plasma, and each of the remaining process chambers 150b, . . . , 150n may use a different plasma source from the microwave plasma. However, embodiments are not limited thereto, and the substrate treating apparatus may be provided as each of all of the plurality of process chambers 150a, 150b, . . . , 150n.

The substrate treating apparatus as described below is an example of the substrate treating apparatus using the microwave plasma as a plasma source. However, embodiments are not limited thereto, and structural characteristics of the substrate treating apparatus as described below may be equally applied to the substrate treating apparatus using a plasma source other than the microwave plasma. For example, the structural characteristics of the substrate treating apparatus as described below may be equally applied to a substrate treating apparatus using capacitively coupled plasma (CCP) as a plasma source, a substrate treating apparatus using inductively coupled plasma (ICP) as a plasma source, a substrate treating apparatus using a mixture of CCP and ICP as a plasma source, a substrate treating apparatus using helicon plasma as a plasma source, etc.

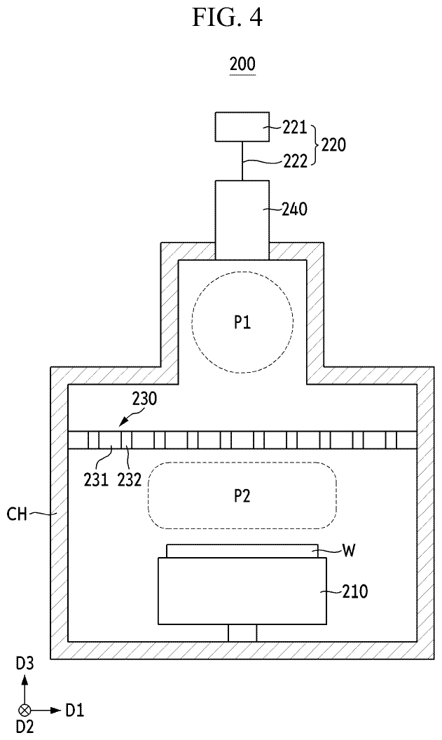

FIG. 4 is a diagram illustrating an internal structure of a substrate treating apparatus according to one or more embodiments. A substrate treating apparatus 200 may treat the substrate W in a vacuum environment. Referring to FIG. 4, the substrate treating apparatus 200 may include a chamber housing CH, a substrate support 210, a process gas supply 220, a showerhead 230, and a plasma generator 240.

The chamber housing CH provides a space where a process for treating the substrate W using plasma (i.e., a plasma process) is performed. The chamber housing CH may be made of alumite having an anodic oxide film formed on its surface, and an inner space thereof may be configured to be airtight. The chamber housing CH may be provided in a cylindrical shape. However, embodiments are not limited thereto and the chamber housing CH may be provided in other shapes.

The chamber housing CH may include an exhaust hole defined at a bottom thereof. The exhaust hole may be connected to an exhaust line on which a pump is mounted. The exhaust hole may discharge the reaction by-product produced during the plasma process and the gas remaining in the chamber housing CH to the outside out of the chamber housing CH through the exhaust line. In this case, the inner space of the chamber housing CH may be depressurized.

The chamber housing CH may include an opening provided as a passage through which the substrate W enters and exits the chamber housing CH. The opening may be formed to extend through a sidewall of the chamber housing CH. The opening may be automatically opened and closed by a door assembly. The door assembly may open and close the opening using one selected from a motor, a hydraulic cylinder, and a pneumatic cylinder.

The substrate support 210 may be installed in a lower area of the inner space of the chamber housing CH. The substrate support 210 may absorb and support the substrate W using an electrostatic force. For example, the substrate support 210 may be embodied as an electrostatic chuck (ESC). However, embodiments are not limited thereto, and the substrate support 210 may support the substrate W thereon using various other schemes such as vacuum, mechanical clamping, etc.

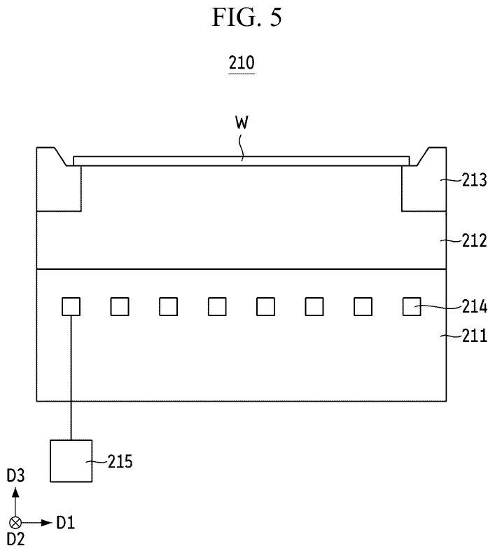

FIG. 5 is a diagram illustrating a substrate support constituting a substrate treating apparatus according to one or more embodiments. Referring to FIG. 5, when the substrate support 210 is embodied as the ESC, the substrate support 210 may be configured to include a base plate 211, a chucking plate 212, a focus ring 213, a cooling member 214, and a cooling device 215.

The base plate 211 may be made of a material having excellent corrosion resistance and heat resistance. For example, the base plate 211 may be provided as an aluminum plate. The chucking plate 212 may be disposed on the base plate 211 and may adsorb and support the substrate W seated thereon. A conductor layer instead of the chucking plate 212 may be formed on the base plate 211. For example, the chucking plate 212 may be embodied as a ceramic puck.

The substrate support 210 may be configured to further include a bonding layer. The bonding layer may bond the base plate 211 and the chucking plate 212 to each other. The bonding layer may include, for example, a polymer.

The focus ring 213 may be provided to surround an outer edge area of the chucking plate 212. The focus ring 213 may play a role in concentrating ions on the substrate W when the plasma process is performed inside the chamber housing CH. In one or more embodiments, the focus ring 213 may be made of silicon.

The substrate support 210 may further include an edge ring. The substrate support 210 may include a ring assembly composed of the focus ring 213 and the edge ring. The edge ring may cover an outer surface of the focus ring 213. The edge ring may prevent the focus ring 213 from being etched. The edge ring may cover the outer surfaces of the base plate 211 and the chucking plate 212 as well as the focus ring 213. The edge ring may prevent the side surfaces of the base plate 211 and the chucking plate 212 from being damaged by the plasma. The edge ring may be made of an insulator material. For example, the edge ring may be made of quartz or ceramic.

The cooling member 214 may be provided to maintain the substrate W at a process temperature when the substrate treating process is performed inside the chamber housing CH. The cooling member 214 may be installed inside the base plate 211 and may be embodied as a cooling pipe through which a coolant flows. The cooling device 215 may supply the coolant to the cooling member 214. The cooling device 215 may use cooling water as the coolant. However, embodiments are not limited thereto and helium (He) gas may be used as the coolant. Alternatively, the cooling device 215 may use both the cooling water and helium gas as the coolant. In one example, a heating member may be further provided to adjust the temperature of the substrate W to a process temperature.

The present disclosure will be described again with reference to FIG. 4.

The process gas supply 220 may provide process gas to the inner space of the chamber housing CH. The process gas supply 220 may provide process gas to the inner space of the chamber housing CH through a hole extending through an upper surface of the chamber housing CH. However, embodiments are not limited thereto, and the process gas supply 220 may provide the process gas to the inner space of the chamber housing CH through a hole extending through a side surface of the chamber housing CH.

The process gas supply 220 may include a process gas supply source 221 and a process gas supply pipe 222. The process gas supply source 221 may provide gas used to treat the substrate W as the process gas. The process gas supply source 221 may be provided as a single process gas supply source in the substrate treating apparatus 200. However, embodiments are not limited thereto and the substrate treating apparatus 200 may include a plurality of process gas supply sources. In a case where the substrate treating apparatus 200 includes the plurality of process gas supply sources 221, the plurality of process gas supply sources 221 may provide the same type of the process gas. However, embodiments are not limited thereto and the plurality of process gas supply sources 221 may provide different types of process gases.

The showerhead 230 may be disposed in the inner space of the chamber housing CH and may include a showerhead body 231 and a plurality of gas feeding holes 232. The plurality of gas feeding holes 232 may extend through a surface of the showerhead body 231 in the third direction D3. The plurality of gas feeding holes 232 may be spaced apart from each other by a predetermined spacing and may extend through the showerhead body 231. The showerhead 230 may uniformly provide the process gas excited into the plasma state to the entire area of the substrate W through the plurality of gas feeding holes 232.

The showerhead 230 may be installed within the chamber housing CH so as to face the substrate support 210 in the vertical direction D3. The showerhead 230 may be constructed to have a diameter larger than that of the chucking plate 212. However, embodiments are not limited thereto. The showerhead 230 may be constructed to have the diameter equal to the diameter of the chucking plate 212. The showerhead 230 may be made of silicon. However, embodiments are not limited thereto and the showerhead 230 may be made of metal.

The plasma generator 240 may generate plasma using the process gas. The plasma generator 240 may excite the process gas flowing to a discharge space into the plasma state. Alternatively, the plasma generator 240 may excite the process gas remaining in the discharge space into the plasma state.

The discharge space may be provided as a plasma area P1. The discharge space may be separated from a process area P2 which is an area in which the substrate W is treated. The plasma area P1 may be positioned at a higher level than that of the showerhead 230 in the chamber housing CH, and the process area P2 may be positioned at a lower level than that of the showerhead 230 in the chamber housing CH. However, embodiments are not limited thereto, and the plasma area P1 may be further provided between the showerhead 230 and the process area P2.

The plasma generator 240 may use microwave plasma as a plasma source. However, embodiments are not limited thereto, and the plasma generator 240 may additionally use another plasma source. For example, the plasma generator 240 may further use ICP as a plasma source. Alternatively, the plasma generator 240 may further use CCP as a plasma source. Alternatively, the plasma generator 240 may further use a mixture of inductively coupled plasma and capacitively coupled plasma as a plasma source. Alternatively, the plasma generator 240 may further use helicon plasma as a plasma source.

When the plasma generator 240 uses the microwave plasma as a plasma source, a detailed description of a structure of the plasma generator 240 will be described later.

The substrate treating apparatus 200 may include a liner. The liner may protect the inside of the chamber housing CH from arc discharge generated during the process of exciting the process gas or impurities generated during the substrate treating process. The liner may be formed to cover an inner wall of the chamber housing CH.

The substrate treating apparatus 200 may include a baffle. The baffle may exhaust process by-products of plasma or unreacted gas in the chamber housing CH to the outside. The baffle may be provided between the substrate support 210 and the inner wall of the chamber housing CH. When the substrate treating apparatus 200 includes the liner surrounding the inner wall of the chamber housing CH, the baffle may be provided between the liner and the substrate support 210. The baffle may be adjacent to the exhaust hole. The baffle may be provided in an annular ring shape.

The baffle may include a main body and a plurality of slot holes extending through the main body in the vertical direction D3 to control the flow of the process gas in the chamber housing CH. The baffle may be made of a material having etch resistance in order to minimize damage thereof or deformation thereof by radicals or the like. For example, the baffle may be made of quartz.

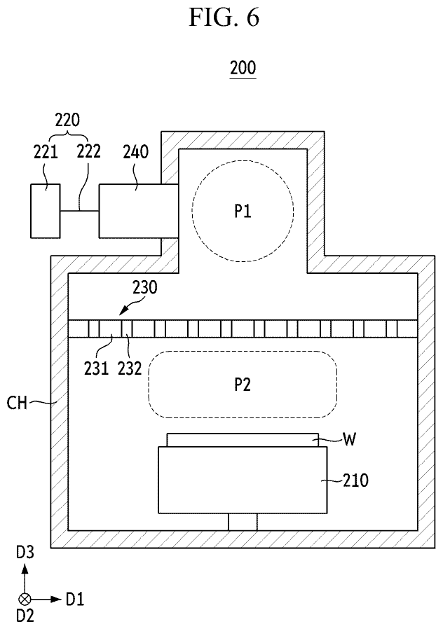

FIGS. 6 to 8 are diagrams illustrating examples of an internal structure of a substrate treating apparatus according to one or more embodiments.

Hereinafter, a description of aspects that are the same as or similar to those described above may be omitted.

Referring to FIG. 4, the plasma generator 240 may be disposed adjacent to an upper surface of the chamber housing CH. In this case, the plasma generator 240 may be connected to the upper surface of the chamber housing CH while extending in a longitudinal direction of the third direction D3. Referring to FIG. 6, the plasma generator 240 may be disposed adjacent to a side surface of the chamber housing CH. In this case, the plasma generator 240 may be connected to the side surface of the chamber housing CH while extending in a longitudinal direction of the first direction D1 or the second direction D2. The plasma generator 240 may be provided in a singular manner, or may be provided in a plural manner. When a plurality of plasma generators 240 are provided, the plasma generators 240 may be arranged so as to be spaced apart from each other at a predetermined spacing along the circumference of the side surface of the chamber housing CH.

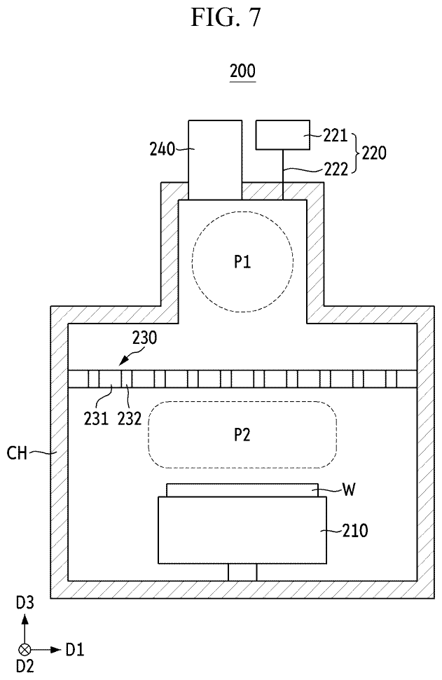

Referring to FIG. 4, the process gas supply 220 may be connected to the plasma generator 240. The process gas provided from the process gas supply 220 may flow to the inner space of the chamber housing CH through the plasma generator 240. The plasma generator 240 may excite the process gas flowing to the plasma area P1 into a plasma state. Referring to FIG. 7, each of the process gas supply 220 and the plasma generator 240 may be connected to the chamber housing CH. The process gas supply 220 may not be connected to the plasma generator 240. That is, the process gas supply 220 and the plasma generator 240 may be separately connected to the chamber housing CH. In other words, as compared to other example embodiments described herein, the process gas supply 220 may be directly connected to the chamber housing CH, and the plasma generator 240 may be directly connected to the chamber housing CH (i.e., as compared to, for example, FIG. 4, where the process gas supply 220 is connected to the plasma generator 240, which is connected to the chamber housing CH). The process gas provided from the process gas supply 220 may flow to the inner space of the chamber housing CH without passing through the plasma generator 240. The plasma generator 240 may excite the process gas remaining in the plasma area P1 into a plasma state.

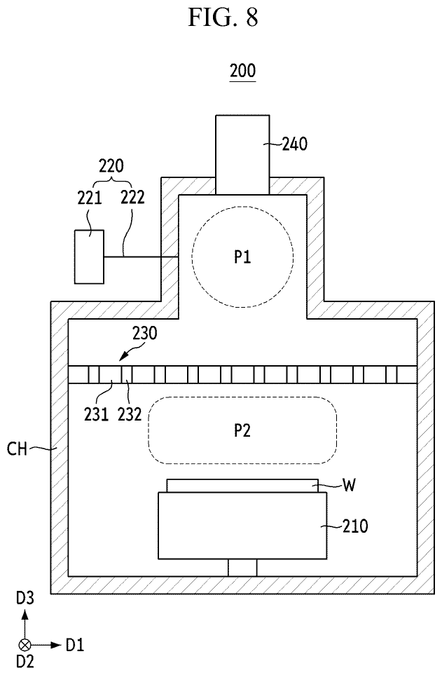

Referring to FIG. 7, the process gas supply 220 and the plasma generator 240 may be connected to the same surface of the chamber housing CH. Each of the process gas supply 220 and the plasma generator 240 may be connected to the side surface of the chamber housing CH. Referring to FIG. 8, the process gas supply 220 and the plasma generator 240 may be connected to different surfaces of the chamber housing CH, respectively. As illustrated in FIG. 8, the plasma generator 240 may be connected to the upper surface of the chamber housing CH, and the process gas supply 220 may be connected to the side surface of the chamber housing CH. However, alternatively, the plasma generator 240 may be connected to the side surface of the chamber housing CH, and the process gas supply 220 may be connected to the upper surface of the chamber housing CH. That is, the process gas supply 220 and the plasma generator 240 may be directly connected to the chamber housing CH on different sides of the chamber housing CH.

Next, a structure of the plasma generator 240 using the microwave plasma as a plasma source will be described.

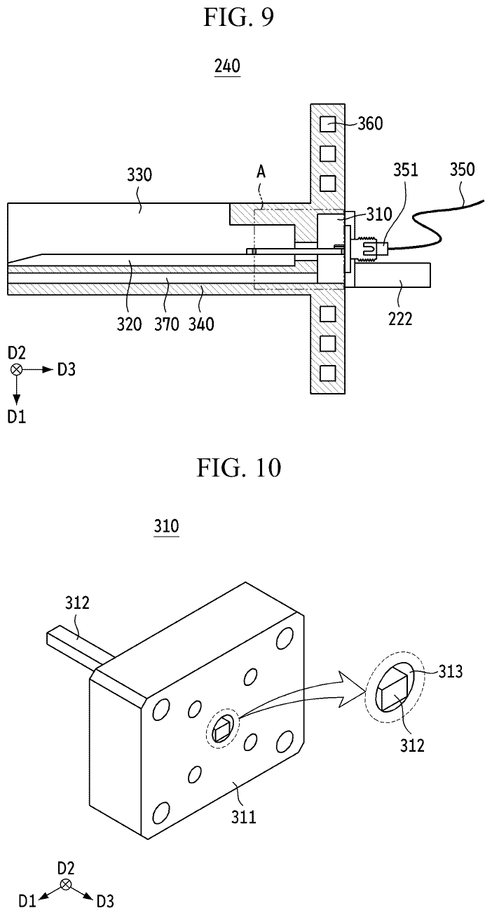

FIG. 9 is a diagram illustrating an internal structure of a plasma generator constituting a substrate treating apparatus according to one or more embodiments. Referring to FIG. 9, the plasma generator 240 may include a connector 310, an antenna 320, a cover 330, and a microwave transmission portion 340.

The plasma generator 240 may be provided as a plasma supply source to enhance plasma stability and reliability. The connector 310 may transmit microwaves from the atmosphere (normal pressure) to the vacuum chamber without impedance change and power loss. The antenna 320 may be a microstrip line-based antenna, and may be designed to transfer the microwave from the connector 310 to an end thereof in a minimizing manner of microwave power loss, and to have an electric field of 0 at a contact portion thereof with the connector 310. The microwave transmission portion 340 may be composed of a dielectric portion, a conductor that transmits microwaves to a center of the dielectric portion, and a ground conductor surrounding the dielectric portion. The microwave transmission portion 340 may supply a uniform amount of gas to the ground electrode and the large area. To this end, the microwave transmission portion 340 may include an internal gas channel. The microwave transmission portion 340 may include a cooling flow path to prevent deterioration of the plasma source. The cover 330 may be provided as a dielectric cover capable of preventing metal oxidation and arcing.

The connector 310 may be inserted into a groove formed in the microwave transmission portion 340. The connector 310 may be formed to be buried in the groove of the microwave transmission portion 340. The connector 310 may be connected to a microwave coaxial cable 350. The connector 310 may excite microwaves between the antenna and a conductor in the connector 310. The connector 310 may be provided as a vacuum connector.

The connector 310 may be formed in a structure capable of transmitting microwaves between the atmosphere and the vacuum chamber without loss of an electric field. The connector 310 may be designed to have a structure capable of receiving the microwaves at the normal pressure (atmospheric pressure) to prevent arcing between the microwave coaxial cable 350 and the antenna 320. The connector 310 may transmit the microwaves input thereto at the normal pressure into the vacuum chamber without loss of an electric field.

FIGS. 10 to 13 are diagrams illustrating examples of a structure of a connector constituting a plasma generator in a substrate treating apparatus according to one or more embodiments. Referring to FIGS. 10 to 13, the connector 310 may include a first dielectric portion 311 and a first conductor 312.

The first dielectric portion 311 may be inserted into the groove formed in the microwave transmission portion 340 to seal the groove. The connector 310 may be provided through the first dielectric portion 311 so that the internal environment of the chamber housing CH maintains a vacuum environment. The connector 310 may be provided so that the internal pressure of the microwave transmission portion 340 maintains a reference value or less. For example, the connector 310 may be provided to maintain the internal pressure of the microwave transmission portion 340 at 0.05 Torr or less.

The first dielectric portion 311 may include a dielectric material. The first dielectric portion 311 may include a dielectric material capable of impedance matching. The first dielectric portion 311 may include a material having a high dielectric constant. The first dielectric portion 311 may include a material having a dielectric constant εᵣ equal to or greater than a reference value. For example, the first dielectric portion 311 may include a material having a dielectric constant εᵣ of 9 or greater. The first dielectric portion 311 may include a material capable of bonding with a metal. The first dielectric portion 311 may include a material having mechanical rigidity. For example, the first dielectric portion 311 may include alumina (Al₂O₃).

The first conductor 312 may be coupled to the first dielectric portion 311. The first conductor 312 may be inserted into a first hole 313 extending through the first dielectric portion 311. A cross-sectional shape of the first conductor 312 may be different from a cross-sectional shape of the first hole 313 defined in the first dielectric portion 311. For example, the cross-sectional shape of the first conductor 312 may be a quadrangle, and the cross-sectional shape of the first hole 313 may be a circle. However, embodiments are not limited thereto, and the cross-sectional shape of the first conductor 312 may be identical with the cross-sectional shape of the first hole 313 defined in the first dielectric portion 311. For example, the cross-sectional shape of the first conductor 312 may be circular, and the cross-sectional shape of the first hole 313 may also be circular.

The first conductor 312 may be inserted into the microwave transmission portion 340 through a second hole 341 formed in the microwave transmission portion 340. One end of the first conductor 312 may be connected to an input end. The input end may be connected to the microwave coaxial cable 350. One end of the first conductor 312 may be connected to the microwave coaxial cable 350. The other end of the first conductor 312 may be adjacent to the antenna 320. The other end of the first conductor 312 may contact or not contact the antenna 320.

The first conductor 312 may include a metal. The first conductor 312 may include a metal having low electrical resistance. The first conductor 312 may include a diamagnetic metal. For example, the first conductor 312 may include a metal having a magnetic permeability close to 1. The first conductor 312 may include a metal capable of bonding with the first dielectric portion 311. The first conductor 312 may include a metal capable of ceramic bonding. Alternatively, the first conductor 312 may include a metal capable of metal brazing. The first conductor 312 may include a metal capable of maintaining a vacuum. For example, the first conductor 312 may include a metal that may be maintained at 0.1 Torr or lower. The first conductor 312 may include a metal that is not oxidized and has mechanical rigidity.

The first dielectric portion 311 and the first conductor 312 may be bonded to each other in a dielectric material-a metal bonding manner in the first hole defined in the first dielectric portion 311. The first dielectric portion 311 and the first conductor 312 may be bonded to each other into an assembly capable of maintaining vacuum. The first dielectric portion 311 and the first conductor 312 may be bonded to each other using one of a method using ceramic bonding, a method using metal brazing, a method using glass bonding, and a method using glass powder. The bonding between the first dielectric portion 311 and the first conductor 312 may be made to maintain airtightness between the first dielectric portion 311 and the first conductor 312.

The connector 310 may transmit microwaves while minimizing electric field loss and impedance change in order to stably implement the plasma. The connector 310 may include a vacuum sealing function so as to be mounted in an atmospheric pressure environment. The connector 310 may not be provided inside the vacuum chamber. The connector 310 may improve durability and prevent arcing.

The connector 310 may be configured such that an impedance Z₀ thereof is equal to a reference value. The connector 310 may be configured such that the impedance Z₀ thereof is equal to the reference value in consideration of a spacing between the conductor and a ground, a thickness of the conductor, etc. The connector 310 may be configured such that the impedance Z₀ thereof is equal to the reference value in consideration of a spacing between the conductor and the ground, a width and a thickness of the conductor, etc. The connector 310 may be configured such that the impedance Z₀ thereof is in a range of 45Ω to 55Ω. The connector 310 may be configured such that the impedance Z₀ thereof is 50Ω. The impedance Z₀ serving as a design reference of the connector 310 may be determined based on Equation (1).

$${Z}_{o} = \frac{138 \times log \frac{d}{{t}_{1}}}{\sqrt{{ε}_{r}}} \approx \frac{60}{\sqrt{{ε}_{r}}} ln \frac{1.9 ( 2 h + {t}_{2} )}{0.8 w + {t}_{2}} \qquad ( 1 )$$

where d denotes a spacing between the conductor and the ground, t₁ and t₂ denote the thickness of the conductor, h denotes a spacing between the conductor and the ground, and w denotes the width of the conductor.

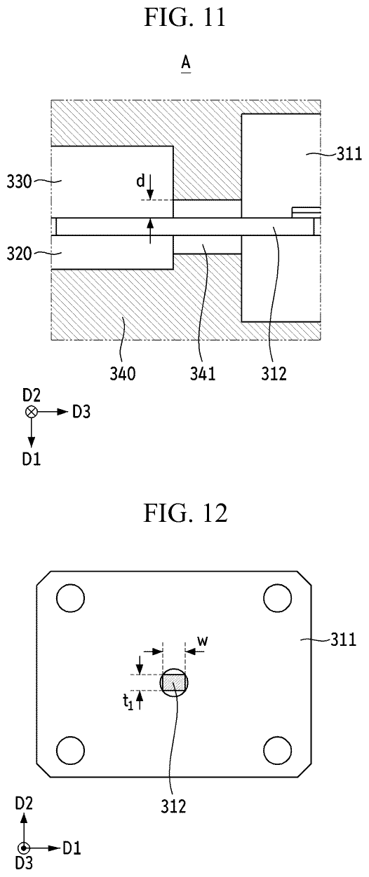

Referring to FIG. 11, when the first conductor 312 is received in and extends through the first dielectric portion 311 and the second hole 341 of the microwave transmission portion 340 into the antenna 320, d may be defined as a spacing between an inner wall of the microwave transmission portion 340 defining the second hole 341 and the first conductor 312.

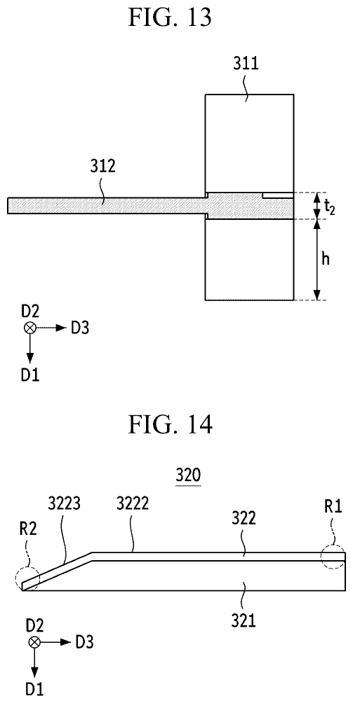

Referring to FIG. 12, t₁ may be defined as a thickness of the first conductor 312. t₁ may be defined as a thickness of a portion of the first conductor 312 exposed out of the first dielectric portion 311. Referring to FIG. 13, t₂ may also be defined as a thickness of the first conductor 312. t₂ may be defined as a thickness of a portion of the first conductor 312 inserted into the first hole 313 defined in the first dielectric portion 311. The thickness of the first conductor 312 may be defined as a length of the first conductor 312 in the second direction D2.

The first conductor 312 may be provided to have a predetermined thickness. A portion of the first conductor 312 inserted into the first dielectric portion 311 and a portion exposed out of the first dielectric portion 311 may be provided to have an equal thickness. t₁ and t₂ may be equal to each other. However, embodiments are not limited thereto, and the first conductor 312 may be provided to have an uneven thickness. A portion of the first conductor 312 inserted into the first dielectric portion 311 and a portion exposed out of the first dielectric portion 311 may be provided to have different thicknesses. t₁ and t₂ may have different values.

Referring to FIG. 13, h may be defined as a distance between the first conductor 312 inserted into the first dielectric portion 311 and an end of the first dielectric portion 311.

Referring to FIG. 12, w may be defined as a width of a portion of the first conductor 312 inserted into the first hole CH1 in the first dielectric portion 311. The width of the first conductor 312 may be defined as a length of the first conductor 312 in the first direction D1. The width of the first conductor 312 may be different from the thickness of the first conductor 312. In this case, w may have a different value from t₁. However, embodiments are not limited thereto, and the width of the first conductor 312 may be equal to the thickness of the first conductor 312. In this case, w may have a value equal to t₁.

The present disclosure will be described again with reference to FIG. 9.

The antenna 320 may be disposed inside the microwave transmission portion 340. That is, at least a portion of the antenna 320 may be provided inside the microwave transmission portion 340. In one or more embodiments, the antenna 320 may be embedded in the microwave transmission portion 340. The inside of the microwave transmission portion 340 may be formed as a vacuum environment by the connector 310. One side of the antenna 320 may be adjacent to the inner wall of the microwave transmission portion 340, and the other side thereof may be adjacent to the cover 330. The antenna 320 may contact or not contact the inner wall of the microwave transmission portion 340. The antenna 320 may contact or not contact the cover 330. The antenna 320 may also be adjacent to the first conductor 312 inserted into the microwave transmission portion 340 through the second hole 341 of the microwave transmission portion 340.

FIGS. 14 to 20 are example diagrams illustrating a structure of an antenna constituting a plasma generator in a substrate treating apparatus according to one or more embodiments.

Referring to FIG. 14, the antenna 320 may include an antenna body 321 and an antenna pattern 322.

The antenna body 321 may be provided as a dielectric substrate. The antenna body 321 may be provided as a single substrate. However, embodiments are not limited thereto, and the antenna body 321 may be provided in a form in which a plurality of substrates are stacked in an overlapping manner. The antenna body 321 may be made of a material having low dielectric material loss of the microwaves and high thermal conductivity. The antenna body 321 may be provided as a flexible substrate having flexibility. The permittivity and thickness of the antenna body 321 may be determined in consideration of the characteristics of the microwaves handled by the plasma generator 240, the shape or characteristics of the substrate treating apparatus 200, etc. For example, the antenna body 321 may include a ceramic material.

The antenna pattern 322 may be provided as a transmission line. The antenna pattern 322 may be made of a conductor. The antenna pattern 322 may be formed on the antenna body 321. The antenna pattern 322 may be provided as a line for transmitting the microwaves. The antenna pattern 322 may be provided as a microstrip line.

The antenna pattern 322 may extend from one end to the other end thereof while being disposed on the antenna body 321. The shape of the antenna pattern 322 may be determined based on an impedance of a microwave circuit, the electric field distribution, the distribution ratio of the microwave power, etc. The antenna pattern 322 may be provided in a predefined shape in consideration of uniform distribution of the microwave power, matching of characteristic impedance, matching of impedance, etc. in designing the microwave circuit.

The antenna pattern 322 may have a structure for preventing arcing, and a transmission length thereof may be determined based on this purpose. The antenna pattern 322 may have a line length L1, L2, L3, or L4 determined so that the electric field is zero in a contact area thereof with the first conductor 312 of the connector 310 as an area vulnerable to the arcing. L1, L2, L3, and L4 will be described later.

The antenna pattern 322 may have the length L1, L2, L3, or L4 of the transmission line optimized to prevent the arcing by bringing the electric field at the contact portion thereof with the first conductor 312 most vulnerable to the arcing to 0. The antenna pattern 322 may contribute to plasma stability. The antenna pattern 322 may be designed to minimize reflection loss and asymmetry between traces so that microwaves are transmitted without loss. The length of the antenna pattern 322 may be determined based on Equation (2).

$$L = ( N / 2 + 0. 25 ) \times λ \pm δ \qquad ( 2 )$$

L denotes the length of the transmission line, that is, the length of the antenna pattern 322. As will be described later, the length of the antenna pattern 322 may be provided as L1, L2, L3, L4, or the like. N denotes a positive integer including 0. For example, N=0, 1, 2, 3, 4, etc. λ denotes a wavelength. λ may be obtained based on the light speed c, a frequency f, and a dielectric constant ∈. δ denotes a fine adjustment component. δ may be applied to adjust the electric field at an input end R1 of the antenna pattern 322 to zero. δ and L have the same length unit value (e.g., mm). However, δ may be 0 in one or more embodiments.

The antenna body 321 may be provided to have an uneven thickness. One end of the antenna body 321 may be provided to have a thickness different from that of the other end of the antenna body 321. The antenna body 321 may include a first portion 3222 having a flat surface and a second portion 3223 having an inclined surface. One end of the antenna body 321 may be provided to have a flat surface (e.g., the first portion 3222), and the other end of the antenna body 321 may be provided to have an inclined surface (e.g., the second portion 3223). The input end R1 of the antenna pattern 322 may be located on the flat surface (e.g., the first portion 3222) of the antenna body 321, and an output end R2 of the antenna pattern 322 may be located on the inclined surface (e.g., the second portion 3223) of the antenna body 321.

The input end R1 of the antenna pattern 322 may be adjacent to the connector 310. The input end R1 of the antenna pattern 322 may contact the first conductor 312. The output end R2 of the antenna pattern 322 may be adjacent to the chamber housing CH. The input end R1 of the antenna pattern 322 may be provided as a single line. The output end R2 of the antenna pattern 322 may also be provided as a single line. However, embodiments are not limited thereto, and the output end R2 of the antenna pattern 322 may be provided as a plurality of lines.

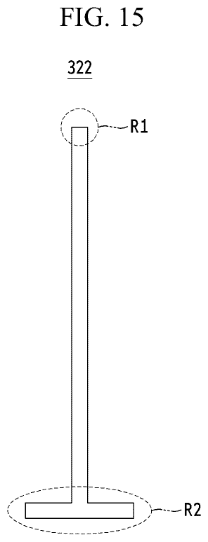

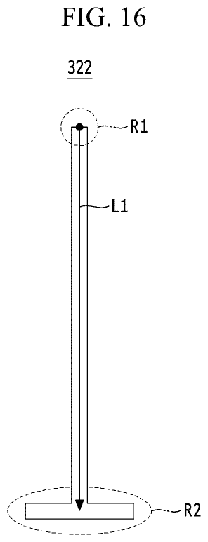

Referring to FIGS. 15 and 16, each of the input end R1 and the output end R2 of the antenna pattern 322 may be provided as a single line.

Referring to FIG. 15, the input end R1 of the antenna pattern 322 may have a width different from that of the output end R2 of the antenna pattern 322. The width of the output end R2 of the antenna pattern 322 may be greater than the width of the input end R1 of the antenna pattern 322. Referring to FIG. 16, the length of the antenna pattern 322 may be provided as L1. The antenna pattern 322 of FIG. 15 may be provided as a single pattern on the antenna body 321. However, embodiments are not limited thereto and the antenna pattern 322 may be provided as a plurality of patterns.

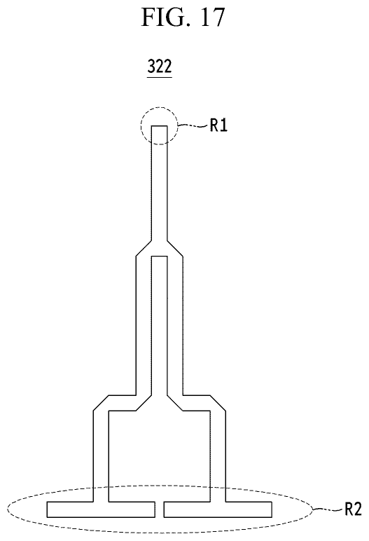

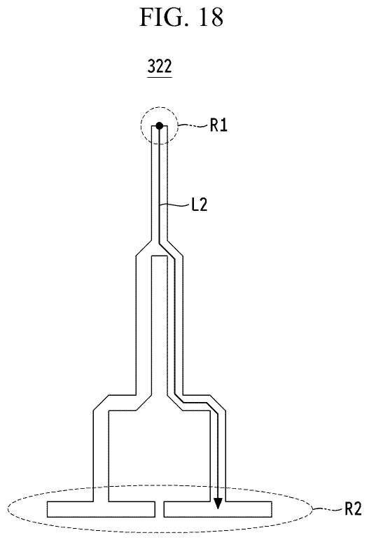

Referring to FIGS. 17 and 18, the input end R1 of the antenna pattern 322 may be provided as a single line, and the output end R2 of the antenna pattern 322 may be provided as a plurality of lines.

Referring to FIG. 17, the input end R1 of the antenna pattern 322 may have a width different from that of each of the output ends R2 of the antenna pattern 322. The width of each of the output ends R2 of the antenna pattern 322 may be greater than the width of the input end R1 of the antenna pattern 322. Referring to FIG. 18, the length of the antenna pattern 322 may be provided as L2. The antenna pattern 322 of FIG. 17 may be provided as a single pattern on the antenna body 321. However, embodiments are not limited thereto and the antenna pattern 322 may be provided as a plurality of patterns. The antenna pattern 322 may be provided only in the shape of FIG. 17. However, embodiments are not limited thereto, and the antenna pattern 322 may have a combination of the shape of FIG. 15 and the shape of FIG. 17.

When a left end R2 of the antenna pattern 322 is defined as a first output end and a right end R2 thereof is defined as a second output end, a line extending from the input end R1 of the antenna pattern 322 to the first output end thereof may have the same shape as that of a line extending from the input end R1 of the antenna pattern 322 to the second output end thereof.

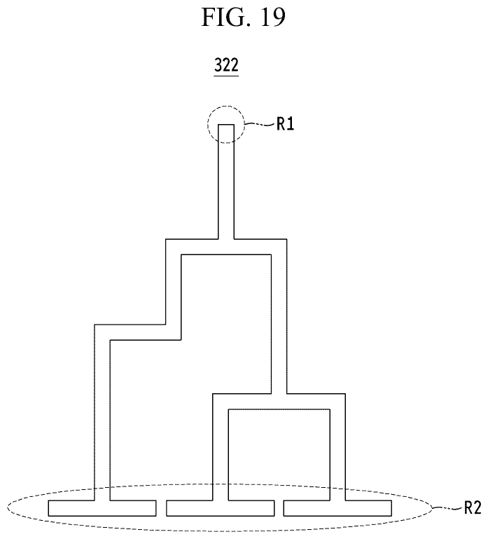

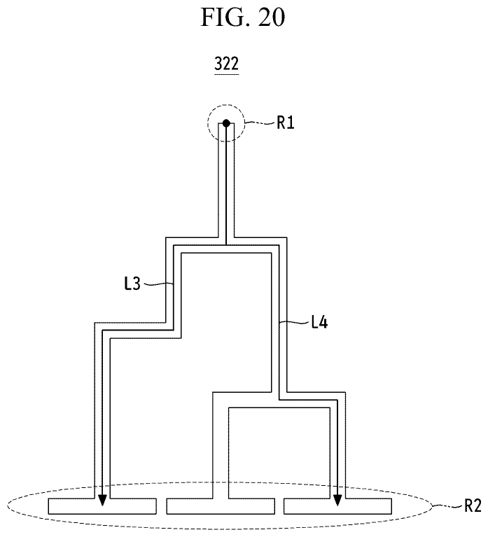

Referring to FIGS. 19 and 20, the input end R1 of the antenna pattern 322 may be provided as a single line, and the output end R2 of the antenna pattern 322 may be provided as a plurality of lines.

Referring to FIG. 19, the input end R1 of the antenna pattern 322 may have a width different from that of each of the output ends R2 of the antenna pattern 322. The width of each of the output ends R2 of the antenna pattern 322 may be greater than the width of the input end R1 of the antenna pattern 322. Referring to FIG. 20, the length of the antenna pattern 322 may be provided as L3. In addition, the length of the antenna pattern 322 may be provided as L4. The antenna pattern 322 of FIG. 19 may be provided as a single pattern on the antenna body 321. However, embodiments are not limited thereto and the antenna pattern 322 may be provided as a plurality of patterns. The antenna pattern 322 may be provided only in the shape of FIG. 19. However, embodiments are not limited thereto, and the antenna pattern 322 may further include at least one of the shape of FIG. 15 and the shape of FIG. 17.

When the left end R2 of the antenna pattern 322 is defined as a third output end, the middle end thereof is defined as a fourth output end, and the right end thereof is defined as a fifth output end, a line extending from the input end R1 of the antenna pattern 322 to the third output end thereof may be provided in a shape different from that of a line extending from the input end R1 of the antenna pattern 322 to the fourth output end thereof. In addition, a line extending from the input end R1 of the antenna pattern 322 to the third output end thereof may be provided in a shape different from that of the line extending from the input end R1 of the antenna pattern 322 to the fifth output end thereof. The line extending from the input end R1 of the antenna pattern 322 to the third output end thereof may be provided to have a length of L3. Each of the line extending from the input end R1 of the antenna pattern 322 to the fourth output end thereof and the line extending from the input end R1 of the antenna pattern 322 to the fifth output end thereof may be provided to have a length of L4. The L3 length may be different than the L4 length. However, embodiments are not limited thereto, and the L3 length may be equal to the L4 length.

The present disclosure will be described again with reference to FIG. 9.

The cover 330 may be provided as a dielectric member for preventing metal oxidation and arcing. The cover 330 may be provided to prevent arcing at other peak points due to a short wavelength in terms of the microwave characteristics. To this end, the cover 330 may be provided to have a thickness of 1.5 times or greater of the thickness of the antenna 320. The cover 330 may be disposed inside the microwave transmission portion 340. That is, at least a portion of the cover 330 may be provided inside the microwave transmission portion 340. In one or more embodiments, the cover 330 may be embedded in the microwave transmission portion 340. The cover 330 may be formed to cover the other side surface of the antenna 320. When one side surface of the antenna 320 contacts the inner wall of the microwave transmission portion 340, the cover 330 may be formed to contact the other side surface of the antenna 320 that does not contact the inner wall of the microwave transmission portion 340. The cover 330 may include a dielectric material.

The microwave coaxial cable 350 may be connected to the input terminal 351. The input terminal 351 and the first conductor 312 may be coupled to the first dielectric portion 311. The input terminal 351 may not be disposed inside the microwave transmission portion 340 and may be exposed to the outside. The first conductor 312 may be disposed inside the microwave transmission portion 340 and may not be exposed to the outside. The input terminal 351 and the first conductor 312 may be connected to each other. The input terminal 351 may excite microwaves between the first conductor 312 and the antenna pattern 322.

The microwave transmission portion 340 may serve as a ground electrode. The microwave transmission portion 340 may isolate the gas supply and the plasma source from each other to maintain the vacuum. The microwave transmission portion 340 may simultaneously serve as a gas channel and a ground electrode. The microwave transmission portion 340 may include a flow path 360 and a gas channel 370 therein.

The flow path 360 may be provided for temperature control. The flow path 360 may be provided to prevent deterioration of the plasma source. The refrigerant may flow in the flow path 360. For example, the coolant may flow in the flow path 360. The flow path 360 may extend in a direction parallel to the width direction of the first dielectric portion 311. The flow path 360 may extend in a direction not parallel to the longitudinal direction of the first conductor 312. The flow path 360 may extend in a direction not parallel to the longitudinal direction of the antenna 320. The flow path 360 may extend in the first direction D1.

The gas channel 370 may be provided to supply a process gas. The gas channel 370 may be connected to a process gas supply pipe 222. The gas channel 370 may extend through the first dielectric portion 311 and then toward the chamber housing CH. The gas channel 370 may extend in a direction parallel to the longitudinal direction of the first conductor 312. The gas channel 370 may extend in a direction parallel to the longitudinal direction of the antenna 320. The gas channel 370 may extend in the third direction D3.

The plasma generator 240 may be connected to the process gas supply 220. However, embodiments are not limited thereto, and the plasma generator 240 may not be connected to the process gas supply 220. In this case, the plasma generator 240 and the process gas supply 220 may be connected to the chamber housing CH, respectively.

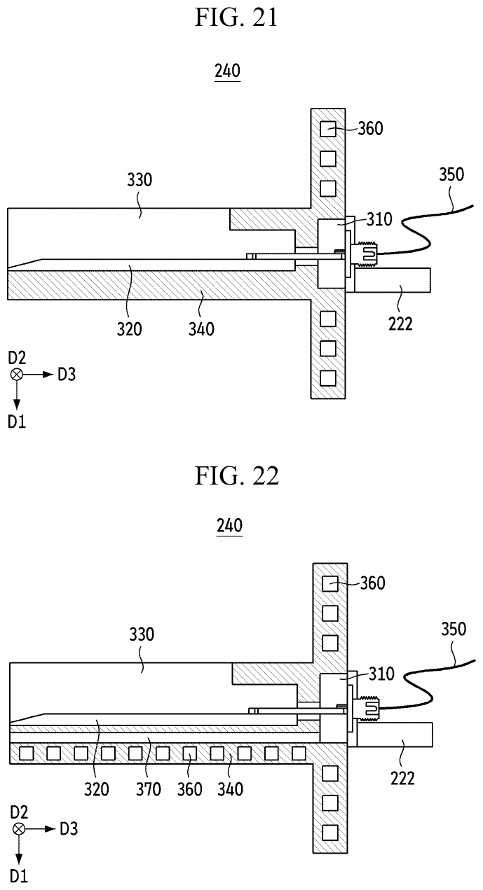

FIGS. 21 and 22 are example diagrams illustrating an internal structure of a plasma generator constituting a substrate treating apparatus according to one or more embodiments.

Referring to FIG. 21, when the plasma generator 240 is not connected to the process gas supply 220, the gas channel 370 may not be installed in the microwave transmission portion 340.

The flow path 360 may be additionally formed so as to extend along the longitudinal direction of the antenna 320. Referring to FIG. 22, the flow path 360 may extend through the first dielectric portion 311 and toward the chamber housing CH. The flow path 360 may extend in a direction parallel to the longitudinal direction of the first conductor 312. The flow path 360 may extend in a direction parallel to the longitudinal direction of the antenna 320. The flow path 360 may extend in the third direction D3.

When both the flow path 360 and the gas channel 370 extend along the longitudinal direction of the antenna 320, the gas channel 370 may be located inwardly of the flow path 360. That is, the gas channel 370 may be disposed closer to the antenna 320 than the flow path 360 may be. However, embodiments are not limited thereto, and the flow path 360 may be located inwardly of the gas channel 370. In this case, the flow path 360 may be disposed closer to the antenna 320 than the gas channel 370 may be.

The plasma generator 240 may be provided as a single plasma generator. However, embodiments are not limited thereto, and the plasma generator 240 may be provided as a plurality of plasma generators. When the plasma generator 240 is installed as shown in FIG. 4, the plasma generators may be arranged so as to be spaced from each other by a regular spacing in the first direction D1. When the plasma generator 240 is installed as shown in FIG. 5, the plasma generators may be arranged so as to be spaced from each other by a regular spacing in the third direction D3.

The plasma generator 240 is a high-density low-temperature plasma generation apparatus based on a microstrip line. The plasma generator 240 may maintain an internal pressure of the substrate treating apparatus 200 acting as a vacuum chamber at 0.01 Torr to 760 Torr, and may maintain an impedance of 50Ω (±0 to 10%).

The plasma generator 240 may reduce deterioration of the plasma source and may improve unstable plasma ignition problem. In addition, the plasma generator 240 may improve an arcing issue. The plasma generator 240 may improve reliability of the plasma source.

The plasma generator 240 may include an arcing-less vacuum connector, a lid integrated ground gas channel including a cooling path, a transmission line L, etc. The plasma generator 240 may have a wider pressure range and a lower electron density in the same high-density plasma compared to an apparatus using a slot antenna. The plasma generator 240 may be applied to situations in which high-pressure, high-density, and low-temperature radicals are required, and may be provided as a plasma source for the plasma that satisfies all the above three characteristics.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate treating apparatus comprising:
a chamber housing;
a substrate support in the chamber housing and configured to support a substrate;
a process gas supply connected to the chamber housing and configured to supply a process gas; and
a plasma generator configured to generate plasma in the chamber housing using a microwave,
wherein the plasma generator comprises:
an antenna;
a connector connecting the antenna to a coaxial cable configured to provide the microwave;
a cover covering the antenna; and
a microwave transmission portion connected to the connector,
wherein at least a portion of the antenna and at least a portion of the cover are inside the microwave transmission portion, and
wherein the connector seals an inside of the microwave transmission portion in a vacuum state.

2. The substrate treating apparatus of claim 1, wherein the connector comprises:
a first dielectric portion sealing the microwave transmission portion; and
a first conductor passing through a first hole extending through the first dielectric portion and bonded to the first dielectric portion.

3. The substrate treating apparatus of claim 2, wherein the antenna comprises an antenna pattern, and
wherein a portion of the antenna pattern contacting the first conductor has an electric field of zero.

4. The substrate treating apparatus of claim 2, wherein the bonding between the first dielectric portion and the first conductor is configured to maintain internal pressure of the microwave transmission portion.

5. The substrate treating apparatus of claim 4, wherein the bonding between the first dielectric portion and the first conductor comprises at least one of ceramic bonding, metal brazing, glass bonding, and glass powder bonding.

6. The substrate treating apparatus of claim 1, wherein a value of an impedance of the plasma generator is within a predetermined range.

7. The substrate treating apparatus of claim 6, wherein the connector comprises a first conductor inside the microwave transmission portion, and
wherein the impedance of the plasma generator is determined based on a spacing between the first conductor and an inner surface of the microwave transmission portion, a width of the first conductor, and a thickness of the first conductor.

8. The substrate treating apparatus of claim 1, wherein the antenna comprises:
an antenna body comprising a dielectric substrate; and
an antenna pattern on the antenna body and configured as a transmission line.

9. The substrate treating apparatus of claim 8, wherein the antenna body comprises a ceramic material.

10. The substrate treating apparatus of claim 8, wherein the antenna pattern is configured as a microstrip line.

11. The substrate treating apparatus of claim 8, wherein the connector comprises a first conductor inside the microwave transmission portion, and
wherein a length of the antenna pattern is determined based on a wavelength of the microwave and an electric field at a portion of the antenna pattern contacting the first conductor.

12. The substrate treating apparatus of claim 8, wherein an upper surface of the antenna body comprises a first portion having a flat surface and a second portion having an inclined surface.

13. The substrate treating apparatus of claim 12, wherein an input end of the antenna pattern is on the first portion having the flat surface, and an output end of the antenna pattern is on the second portion having the inclined surface.

14. The substrate treating apparatus of claim 13, wherein the input end of the antenna pattern is provided as a single line, and the output end of the antenna pattern is provided as a single line or a plurality of lines.

15. The substrate treating apparatus of claim 1, wherein the cover comprises a dielectric material,
wherein a thickness of the cover is 1.5 times or greater than a thickness of the antenna.

16. The substrate treating apparatus of claim 1, wherein the microwave transmission portion is configured as a ground electrode.

17. The substrate treating apparatus of claim 1, wherein the microwave transmission portion comprises a gas channel therein that is connected to the process gas supply.

18. The substrate treating apparatus of claim 1, wherein the microwave transmission portion comprises a flow path therein and configured to be supplied with a refrigerant.

19. A substrate treating apparatus comprising:
a chamber housing;
a substrate support in the chamber housing and configured to support a substrate;
a process gas supply connected to the chamber housing and configured to supply a process gas; and
a plasma generator configured to generate plasma in the chamber housing using a microwave,
wherein the plasma generator comprises:
an antenna;
a connector connecting the antenna to a coaxial cable configured to provide the microwave;
a cover covering the antenna; and
a microwave transmission portion connected to the connector,
wherein at least a portion of the antenna and at least a portion of the cover are inside the microwave transmission portion,
wherein the connector seals an inside of the microwave transmission portion in a vacuum state, and
wherein the process gas supply is configured to supply the process gas to an inner space of the chamber housing via the plasma generator.

20. A substrate treating apparatus comprising:
a chamber housing;
a substrate support in the chamber housing and configured to support a substrate;
a process gas supply connected to the chamber housing and configured to supply a process gas; and
a plasma generator configured to generate plasma in the chamber housing using a microwave,
wherein the plasma generator comprises:
an antenna;
a connector connecting the antenna to a coaxial cable configured to provide the microwave;
a cover covering the antenna; and
a microwave transmission portion connected to the connector,
wherein at least a portion of the antenna and at least a portion of the cover are inside the microwave transmission portion,
wherein the connector seals an inside of the microwave transmission portion in a vacuum state,
wherein the process gas supply is directly connected to the chamber housing, and
wherein the plasma generator is directly connected to the chamber housing.
